(19) United States
(12) Patent Application Publication
(10) Pub. No.: US 2022/0070569 A1
(43) Pub. Date: Mar. 3, 2022

(54) WATER-PROOF MICROPHONE

(71) Applicants: ZILLTEK TECHNOLOGY (SHANGHAI) CORP., Shanghai (CN); ZILLTEK TECHNOLOGY CORP., Hsinchu City (TW)

(72) Inventor: Jinghua Ye, Shanghai (CN)

(73) Assignees: ZILLTEK TECHNOLOGY (SHANGHAI) CORP; ZILLTEK TECHNOLOGY CORP

(21) Appl. No.: 17/094,371

(22) Filed: Nov. 10, 2020

(30) Foreign Application Priority Data
Aug. 28, 2020 (CN) 202010889725.6

(51) Int. Cl. H04R 1/08; H04R 1/04; H04R 3/00

(52) U.S. Cl. CPC H04R 1/083; H04R 3/00; H04R 1/04

(57) ABSTRACT

A water-proof microphone is provided in embodiments of the present invention, comprising: a substrate on which microphone components are mounted; a packaging housing arranged on top of the substrate; a plurality of water-proof sound apertures being formed on the packaging housing; wherein the packaging housing is connected to the substrate in a leak-tight manner. In the present invention, a plurality of water-proof sound apertures are formed on the packaging housing of the microphone, and the water-proof sound apertures prevent water drops from entering the interior of the microphone while allowing sound signals enter the microphone. Water tension may prevent the water drops from entering the microphone through the sound apertures. In this way, the microphone is resistant to water and its acoustic performance is not affected. In addition, since there is no need for the provision of the water-proof membranes, a simpler structure is obtained, and costs are reduced.

### BACKGROUND OF THE INVENTION

### 1. Field of the Invention

The invention relates to the field of microphones, and more particularly, to a water-proof microphone.

### 2. Description of the Related Art

A MEMS (Micro Electro Mechanical System) microphone is capable of providing high performance, high fidelity and reliability with a compact size, so that it is suitable for portable devices. The existing MEMS microphone can be produced using surface mounting technology, and has the ability to withstand an extremely high reflow soldering temperature; it can be easily integrated with CMOS processes and other audio circuits; and it has improved noise cancellation performance and good RF and EMI suppression effects.

Microphones commercially available in the market are rarely water-proof. For those water-proof microphones, water-proof membranes may be arranged outside or inside of the microphones. However, the water-proof membranes may block the transmission of some sound signals. As a result, volume may be weakened, and the volume and sound quality of the microphone are decreased.

### SUMMARY OF THE INVENTION

An object of the present invention is to provide a water-proof microphone to solve the above-mentioned technical problems.

The technical problems in the present invention can be solved by adopting the following technical solutions:

a water-proof microphone, comprising:

a substrate on which microphone components are mounted;

a packaging housing arranged on top of the substrate; a plurality of water-proof sound apertures being formed on the packaging housing;

wherein the packaging housing is connected to the substrate in a leak-tight manner.

Preferably, the microphone components comprise an acoustic sensor disposed on a top surface of the substrate and an ASIC (Application Specific Integrated Circuit) chip, the acoustic sensor is electrically connected to the ASIC chip.

Preferably, the plurality of water-proof sound apertures are provided on sides of the packaging housing.

Preferably, the plurality of water-proof sound apertures are provided on top of the packaging housing.

Preferably, the plurality of water-proof sound apertures are arranged in rows, a connecting line between centres of any two of the plurality of water-proof sound apertures is parallel to a top surface of the packaging housing.

Preferably, the plurality of water-proof sound apertures are arranged in columns, a connecting line between centres of any two of the plurality of water-proof sound apertures is perpendicular to a top surface of the packaging housing.

Preferably, the plurality of water-proof sound apertures are arranged on the packaging housing in a matrix manner Preferably, each of the plurality of water-proof sound apertures has an inner diameter ranging from 0.01 mm to 0.03 mm.

Preferably, each of the plurality of water-proof sound apertures has an inner diameter of 0.02 mm.

Preferably, the substrate is connected to the packaging housing by sealant.

By adopting the above-mentioned technical solutions, the present invention has the beneficial effects that a plurality of water-proof sound apertures are formed on the packaging housing of the microphone, and water tension may prevent water drops from entering the microphone through the sound apertures. In this way, external sound may smoothly enter an acoustic cavity inside the microphone from the water-proof sound apertures, such that the microphone is resistant to water and its acoustic performance is not affected. In addition, since there is no need for the provision of the water-proof membranes, a simpler structure is obtained, and costs are reduced.

### BRIEF DESCRIPTION OF THE DRAWINGS

The accompanying drawings, together with the specification, illustrate exemplary embodiments of the present disclosure, and, together with the description, serve to explain the principles of the present invention.

FIG. 1 shows a schematic diagram of a microphone according to the present invention in a sectional view;

FIG. 2 shows a first arrangement in which a plurality of water-proof sound apertures are formed on a packaging housing of the microphone according to the present invention;

FIG. 3 shows a second arrangement in which a plurality of water-proof sound apertures are formed on a packaging housing of the microphone according to the present invention;

FIG. 4 shows a third arrangement in which a plurality of water-proof sound apertures are formed on a packaging housing of the microphone according to the present invention; and

FIG. 5 shows a fourth arrangement in which a plurality of water-proof sound apertures are formed on a packaging housing of the microphone according to the present invention.

In the accompanying drawings: 1—substrate; 2—microphone component; 3—packaging housing; 4—acoustic sensor; 5—ASIC chip; 30—water-proof sound aperture.

### DETAILED DESCRIPTION

The technical solution set forth in the embodiments of the present invention will now be described clearly and fully hereinafter with reference to the accompanying drawings of the embodiments of the present invention. Obviously, such embodiments provided in the present invention are only part of the embodiments instead of all embodiments. It should be understood that all the other embodiments obtained from the embodiments set forth in the present invention by one skilled in the art without any creative work fall within the scope of the present invention.

Notably, the embodiments set forth in the present invention and features of the embodiments may be combined in any suitable manner.

The present invention will be described hereinafter with reference to the accompanying drawings and particular embodiments, but the invention is not limited thereto.

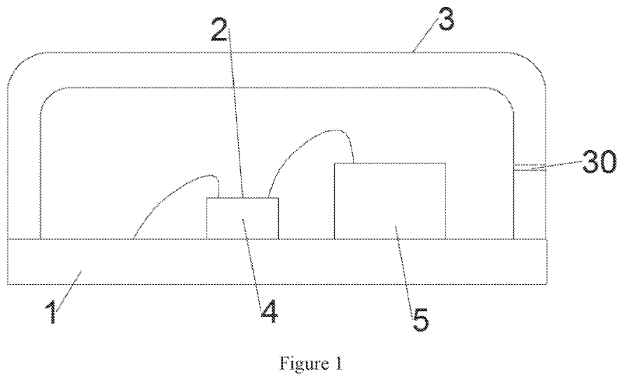

As shown in FIG. 1, the invention provides a water-proof microphone, comprising:

a substrate 1 on which microphone components 2 are mounted;

a packaging housing 3 arranged on top of the substrate 1; a plurality of water-proof sound apertures 30 being formed on the packaging housing 3;

wherein the packaging housing 3 is connected to the substrate 1 in a leak-tight manner.

By adopting the above-mentioned technical solutions, the present invention has the beneficial effects that a plurality of water-proof sound apertures are formed on the packaging housing of the microphone, and the water-proof sound apertures prevent water drops from entering the interior of the microphone while allowing sound signals enter the microphone. Water tension may prevent the water drops from entering the microphone through the sound apertures. In this way, the microphone is resistant to water and its acoustic performance is not affected. In addition, since there is no need for the provision of the water-proof membranes, a simpler structure is obtained, and costs are reduced.

According to the principle of water tension: there is a thin layer, called a surface layer, where liquid is in contact with gas, molecules in the surface layer are sparser that those in liquid, and the distance between the molecules of the surface layer is larger than that of liquid. Interactions between the molecules are in the form of gravity, i.e., surface tension. The presence of the surface tension makes it possible for the liquid surface to act as a stretched spring, which always tends to contract. Therefore, when the microphone according to the present invention contacts water, water forms a water film on the water-proof sound apertures to prevent external water from entering the interior of the microphone. When external water pressure is not greater than a certain threshold, water may not enter the interior of the microphone, thus, the microphone is water-proof.

As a preferred embodiment of the present invention, the microphone components 2 comprise an acoustic sensor 4 disposed on a top surface of the substrate and an ASIC (Application Specific Integrated Circuit) chip 5, the acoustic sensor 4 is electrically connected to the ASIC chip 5.

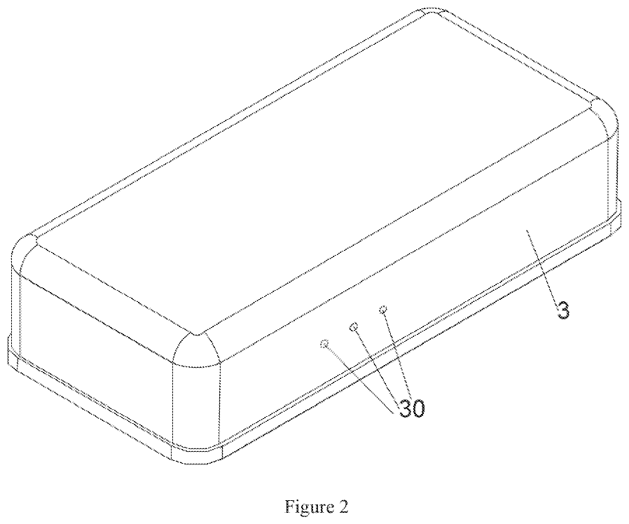

As shown in FIGS. 2, 3 and 4, as a preferred embodiment of the present invention, the plurality of water-proof sound apertures 30 are provided on sides of the packaging housing. The MEMS microphone here functions as microphone device in which sound enters from the side.

As a preferred embodiment of the present invention, each of the plurality of water-proof sound apertures 30 has an inner diameter ranging from 0.01 mm to 0.03 mm. It is therefore ensured that water drops will not enter electrical components inside the microphone through the water-proof sound apertures 30, and circuit components are not corroded. In addition, sound may be input into the interior of the microphone from the water-proof sound apertures 30 without any interference, and the acoustic performance of the water-proof microphone is guaranteed.

As a specific embodiment, each of the plurality of water-proof sound apertures has an inner diameter of 0.02 mm.

As shown in FIG. 2, as a first arrangement in which a plurality of water-proof sound apertures are formed on a packaging housing of the microphone according to the present invention, the plurality of water-proof sound apertures 30 are arranged in rows, a connecting line between centres of any two of the plurality of water-proof sound apertures 30 is parallel to the top surface of the packaging housing 3.

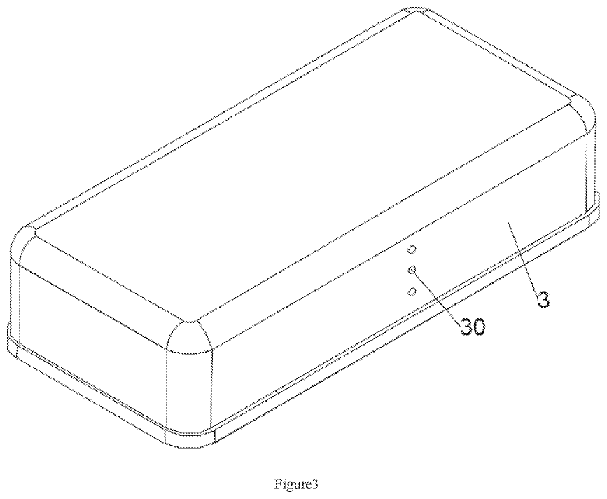

As shown in FIG. 3, as a second arrangement in which a plurality of water-proof sound apertures are formed on a packaging housing of the microphone according to the present invention, when the plurality of water-proof sound apertures are provided on sides of the packaging housing, the plurality of water-proof sound apertures 30 are arranged in columns on the side of the packaging housing, and a connecting line between centres of any two of the plurality of water-proof sound apertures 30 is perpendicular to the top surface of the packaging housing 3.

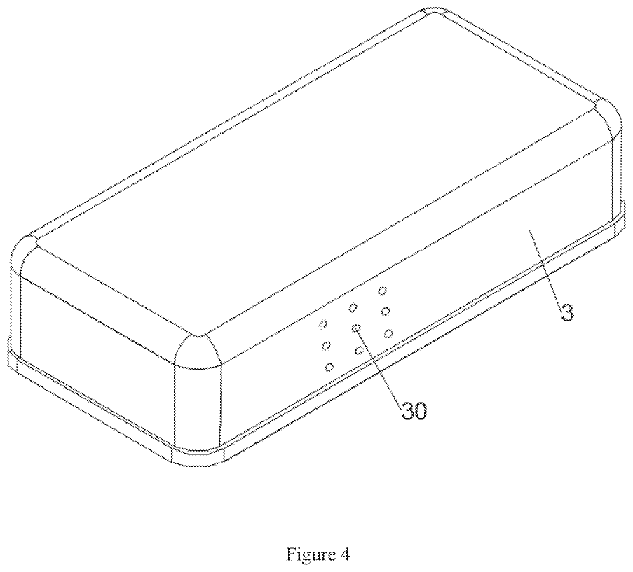

As shown in FIG. 4, as a third arrangement in which a plurality of water-proof sound apertures are formed on a packaging housing of the microphone according to the present invention, the plurality of water-proof sound apertures 30 are arranged on the packaging housing 6 in a matrix manner. The plurality of water-proof sound apertures 30 are arranged on the packaging housing in rows and columns, such that areas for the entry of sound are increased, and the water-proof performance for each of the plurality of water-proof sound apertures is consistent, therefore, the pickup quality of the microphone is improved.

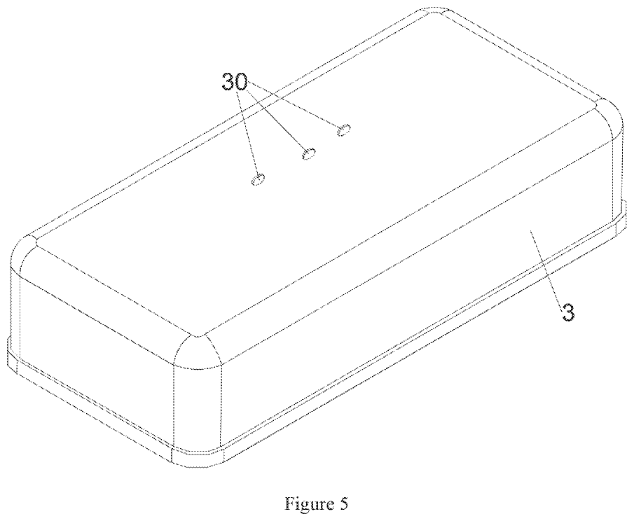

As shown in FIG. 5, as a fourth arrangement in which a plurality of water-proof sound apertures are formed on a packaging housing of the microphone according to the present invention, the water-proof sound apertures can also be provided on top of the packaging housing 3.

As a preferred embodiment of the present invention, the substrate 1 is connected to the packaging housing 3 by sealant. The sealant may fill a connection gap between the substrate and the packaging housing, so that a sealing level of the microphone is guaranteed, water leakage of the packaging housing is avoided, and a better water-proof performance is achieved.

The above descriptions are only the preferred embodiments of the invention, not thus limiting the embodiments and scope of the invention. Those skilled in the art should be able to realize that the schemes obtained from the content of specification and drawings of the invention are within the scope of the invention.

What is claimed is:

1. A water-proof microphone, comprising:
a substrate on which microphone components are mounted;
a packaging housing arranged on top of the substrate; a plurality of water-proof sound apertures being formed on the packaging housing;
wherein the packaging housing is connected to the substrate in a leak-tight manner.

2. The water-proof microphone of claim 1, wherein the microphone components comprise an acoustic sensor disposed on a top surface of the substrate and an ASIC (Application Specific Integrated Circuit) chip, the acoustic sensor is electrically connected to the ASIC chip.

3. The water-proof microphone of claim 1, wherein the plurality of water-proof sound apertures are provided on sides of the packaging housing.

4. The water-proof microphone of claim 1, wherein the plurality of water-proof sound apertures are provided on top of the packaging housing.

5. The water-proof microphone of claim 1, wherein the plurality of water-proof sound apertures are arranged in rows, a connecting line between centres of any two of the plurality of water-proof sound apertures is parallel to a top surface of the packaging housing.

6. The water-proof microphone of claim 1, wherein the plurality of water-proof sound apertures are arranged in columns, a connecting line between centres of any two of the plurality of water-proof sound apertures is perpendicular to a top surface of the packaging housing.

7. The water-proof microphone of claim 1, wherein the plurality of water-proof sound apertures are arranged on the packaging housing in a matrix manner.

8. The water-proof microphone of claim 1, wherein each of the plurality of water-proof sound apertures has an inner diameter ranging from 0.01 mm to 0.03 mm.

9. The water-proof microphone of claim 8, wherein each of the plurality of water-proof sound apertures has an inner diameter of 0.02 mm.

10. The water-proof microphone of claim 1, wherein the substrate is connected to the packaging housing by sealant.
